(19) United States
(12) Patent Application Publication
(10) Pub. No.: US 2007/0080358 A1
(43) Pub. Date: Apr. 12, 2007

(54) White light emitting device

(75) Inventor: Kai-Shyong Tsai, Lujhou City (TW)

Correspondence Address: BACON & THOMAS, PLLC, 625 SLATERS LANE, FOURTH FLOOR, ALEXANDRIA, VA, 22314, US

(73) Assignee: Luminoso Photoelectric Technology Co., Taipei County (TW)

(21) Appl. No.: 11/244,233

(22) Filed: Oct. 6, 2005

(51) Int. Cl. H01L 33/00

(52) U.S. Cl. 257/98; 257/100

(57) ABSTRACT

There is provided a white light emitting device including a light emitting chip, which can emit a first light having a wavelength between 340 nm and 495 nm; an organic phosphor layer, which is formed by applying an organic polymer on the output surface of the light emitting chip using coating, screen printing, offset printing, sputtering, dripping, casting, adhering, or vacuum evaporation method; and an encapsulation layer embedded with a plurality of nanograde crystalline grains, which encloses the light emitting chip and the organic phosphor layer, wherein the first light emitted from the light emitting chip can excite the organic phosphor layer, which subsequently emits a second light having a wavelength between 530 nm and 580 nm, and the second light and the first light are mixed within the encapsulation layer to produce a white light with excellent color uniformity and color rendering outwards from the encapsulation layer.

### BACKGROUND OF THE INVENTION

1. Field of the Invention

The present invention relates generally to a light emitting device, and in particular to a white light emitting device which can emit a white light with excellent color uniformity and color rendering.

2. The Prior Arts

Nowadays, the applications for the white light emitting devices include reading lights on the cars, decorative lamps, and the like. Recently, the white light emitting devices are used as a backlight source for the electronic products with small size, and specifically as a backlight source for a color cell phone and as a flash lamp for a digital camera fitted in a cell phone. As a whole, the white light emitting devices will become a very potential illuminator in the future. However, these white light emitting devices possess several undesirable shortcoming, such as poor color uniformity and poor color rendering, which will affect the quality of the light emitting devices. Most of the phosphors for the light emitting devices are made from inorganic polymers (such as YAG yellow phosphors), for example, the phosphors used in the light emitting device and the display device disclosed in Taiwan patent No. 383508, the new white LED disclosed in Taiwan patent No. 385063, the white LED disclosed in Taiwan patent No. 556365, and the high power white LED disclosed in Taiwan patent No. 465123. When the phosphors are coated on the output surface and the periphery of the light emitting devices (such as LED), the homogeneity and the adhesion can not be controlled well. As a result, the phosphor emission light can not well mix with the light emitted from LED. Consequently, although a human observer may perceive the mixed light as a white light, the mixed light appears as a yellowish halo surrounding a bluish area when projected onto a pure white paper. Therefore, the present invention has been developed as a result of studies to solve the above-mentioned problems.

### SUMMARY OF THE INVENTION

The objective of the present invention is to provide a white light emitting device which can emit a white light with excellent color uniformity and color rendering in order to overcome the problems set forth above.

To achieve the foregoing objective, the present invention provides a white light emitting device, and the white light emitting device comprises: a light emitting chip, functioning as a light source, which can emit a first light having a wavelength between 340 nm and 495 nm; an organic phosphor layer, which is formed by applying an organic polymer on the output surface of the light emitting chip using coating, screen printing, offset printing, sputtering, dripping, casting, adhering, or vacuum evaporation method; and an encapsulation layer embedded with a plurality of nanograde crystalline grains, which encloses the light emitting chip and the organic phosphor layer, wherein the first light emitted from the light emitting chip can excite the organic phosphor layer, which subsequently emits a second light having a wavelength between 530 nm and 580 nm which is different form the first light, and the second light and the first light which is not absorbed by the organic phosphor layer are mutually mixed within the encapsulation layer to produce a mixed light, which is further mixed by focusing and scattering the mixed light with a plurality of nanograde crystalline grains embedded in the encapsulation layer, then emitting a white light with excellent color uniformity and color rendering outwards from the encapsulation layer.

It is worthy to be noticed that the organic polymer applied on the output surface of the light emitting chip to form the organic phosphor layer of the present invention includes:

Melamine-Sulphonamide-Formaldehyde Copolymer Type.

The organic phosphor layer enclosed within the encapsulation layer embedded with a plurality of nanograde crystalline grains is excited by the first light and subsequently emits a second light, which will mix with the first light, and then the mixed light is focused and scattered by nanograde crystalline grains while passing through the encapsulation layer, thus producing a white light with excellent color uniformity and color rendering.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 is a cross-sectional view of a white light emitting device in accordance with the present invention;

FIG. 2 is a flow chart for producing a white light in accordance with the present invention; and

FIG. 3 is a partially enlarged view of the encapsulation layer arranged in the white light emitting device shown in FIG. 1.

### DETAILED DESCRIPTION OF THE PREFERRED EMBODIMENT

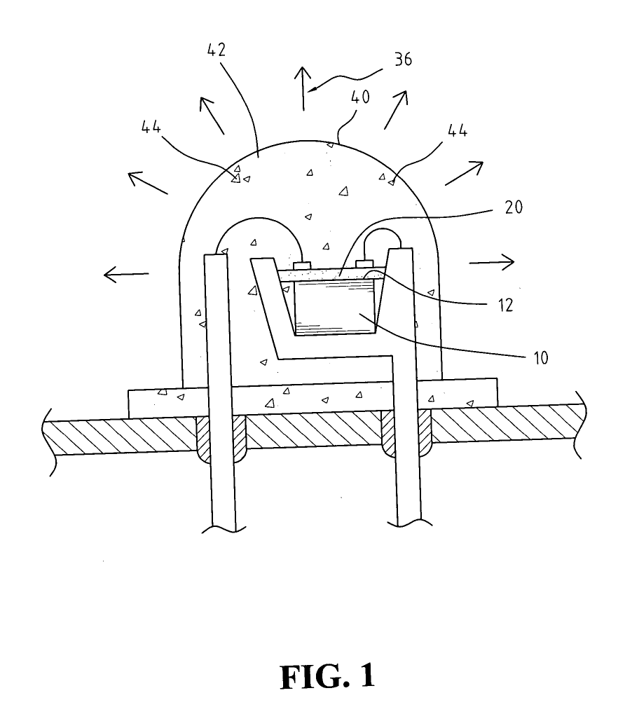

FIG. 1 is a cross-sectional view of a white light emitting device in accordance with the present invention. In FIG. 1, the light emitting chip 10, functioning as a light source, emits a first light having a wavelength between 340 nm and 495 nm (including ultraviole light, violet light, indigo light, and blue light) when subjected to an electric current. The organic phosphor layer 20 is formed by applying the organic polymer (as listed in the following text) on the output surface 12 of the light emitting chip 10 using coating, screen printing, offset printing, sputtering, dripping, casting, adhering, or vacuum evaporation method. The thickness of organic phosphor layer 20 is preferably in the range from 500 Å to 5000 Å, and also can depend on the need of the designer. The organic polymer used in this embodiment includes:

Melamine-Sulphonamide-Formaldehyde Copolymer Type.

The encapsulation layer 40 is composed of well-mixed transparent resin 42 and a plurality of nanograde crystalline grains 44. These nanograde crystalline grains 44 is able to focus and scatter light, and can be transparent or translucent. The particle size of these nanograde crystalline grains 44 is preferably less than 100 nm. These nanograde crystalline grains 44 appear as particles when observed under a microscope, but appear as powders when observed by human eyes. The light emitting device can emit a white light 36 outwards from the encapsulation layer 40, and the white light 36 has excellent color uniformity and color rendering.

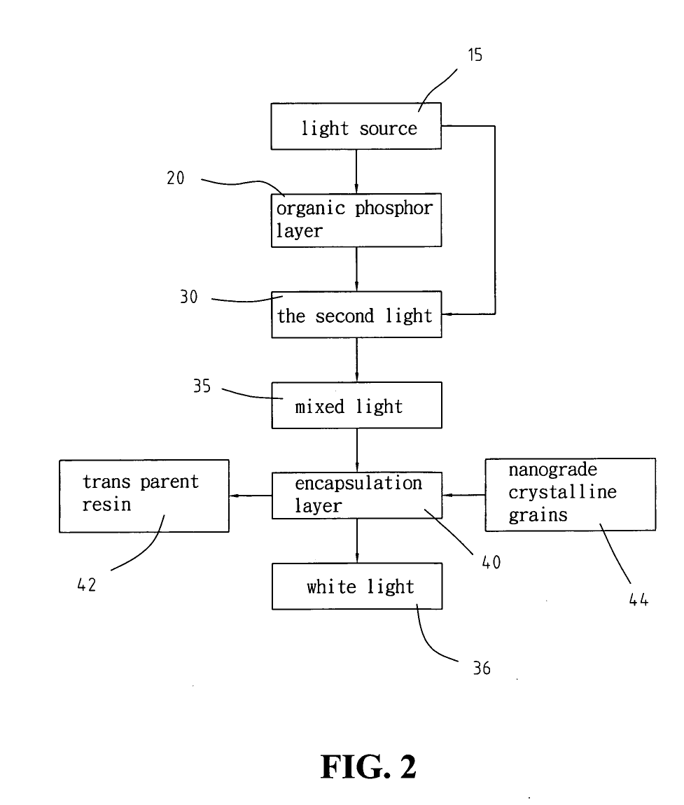

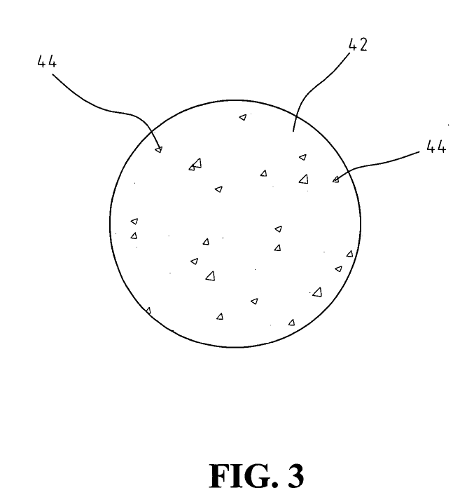

FIG. 2 is a flow chart for producing a white light in accordance with the present invention; and FIG. 3 is a partially enlarged view of the encapsulation layer arranged in the white light emitting device shown in FIG. 1. In FIG.2 and FIG. 3, the light source 15 emits a first light having a wavelength between 340 nm and 495 nm which in turn excites the organic phosphor layer 20. Subsequently, the excited organic phosphor layer 20 emits a second light 30 having a wavelength between 530 nm and 580 nm (i.e. between yellow-green light and yellow-orange light), which is different from the first light. The organic phosphor layer 20 is formed by applying the above-mentioned organic polymer on the output surface 12 of the light emitting chip 10 using coating, screen printing, offset printing, sputtering, dripping, casting, adhering, or vacuum evaporation method. The organic phosphor layer 20 has excellent homogeneity and adhesion because it is formed on the output surface 12 of the light emitting chip 10 by cool forming, which will bring about an improvement in the homogeneity and the intensity of the white light subsequently produced after light mixing. Then, the second light 30 and the first light which is not absorbed by the organic phosphor layer 20 are mixed to produce a mixed light 35 (i.e. a white light). While the mixed light 35 pass through the transparent encapsulation layer 40, it is focused and scattered by a plurality of nanograde crystalline grains 44 embedded in the encapsulation layer 40. Therefore, the white light 36 with excellent color uniformity, color rendering, and intensity will be emitted outwards from the encapsulation layer 40 because the mixed light 35 is further well mixed by focusing and scattering with nanograde crystalline grains 44. The encapsulation layer 40 is composed of a transparent resin 42 and a plurality of nanograde crystalline grains 44. The mixing ratio for the transparent resin 42 and the nanograde crystalline grains 44 is preferably 90:10. These nanograde crystalline grains 44 can be transparent or translucent, and may appear as round shape-, oval shape-, polygon shape-, or irregular shape-nanoparticles.

In another embodiment, the organic polymer (as listed in the above text) are applied on the outside surface of the encapsulation layer 40. The organic polymers may cover substantially all of the outside surface of the encapsulation layer 40.

It will be apparent to those skilled in the art that various modifications and variations can be made in the present invention without departing from the spirit or scope of the present invention. Thus, it is intended that the present invention cover the modifications and the variations of this invention provided they come within the scope of the appended claims and their equivalents.

What is claimed is:

1. A light emitting device for visible light generation, comprising
a light emitting chip, functioning as a light source, which can emit a first light having a wavelength between 340 nm and 495 nm;
an organic phosphor layer, which is formed by applying Melamine-Sulphonamide-Formaldehyde Copolymer Type organic polymer on an output surface of the light emitting chip; and
an encapsulation layer embedded with a plurality of nanograde crystalline grains, which encloses the light emitting chip and the organic phosphor layer,
wherein the first light emitted from the light emitting chip can excite the organic phosphor layer, which subsequently emits a second light which is different from the first light, and the second light and the first light which is not absorbed by the organic phosphor layer are mutually mixed within the encapsulation layer to produce a mixed light, which is further mixed by focusing and scattering the mixed light with a plurality of nanograde crystalline grains embedded in the encapsulation layer, then emitting a visible light with excellent color uniformity and color rendering outwards from the encapsulation layer.

2. The device as claimed in claim 1, wherein a method for applying Melamine-Sulphonamide-Formaldehyde Copolymer Type organic polymer on the output surface of the light emitting chip includes coating, screen printing, offset printing, sputtering, dripping, casting, adhering, or vacuum evaporation.

3. The device as claimed in claim 1, wherein the encapsulation layer is composed of a transparent resin, and the nanograde crystalline grains.

4. The device as claimed in claim 1, wherein the nanograde crystalline grains have a particle size less than 100 nm, which are transparent or translucent.

5. The white light emitting device as claimed in claim 1, wherein the second light has a wavelength between 530 nm and 580 nm.
